(19) United States
(12) Patent Application Publication
(10) Pub. No.: US 2009/0108840 A1
(43) Pub. Date: Apr. 30, 2009

(54) Power Line Sensor

(76) Inventor: Gerald E. Givens, Winnsboro, LA (US)

Correspondence Address: RADER, FISHMAN & GRAUER PLLC, 10653 SOUTH RIVER FRONT PARKWAY, SUITE 150, SOUTH JORDAN, UT, 84095, US

(21) Appl. No.: 12/258,071

(22) Filed: Oct. 24, 2008

Related U.S. Application Data
(60) Provisional application No. 60/982,184, filed on Oct. 24, 2007.

(51) Int. Cl. G01R 19/00; G01R 33/07; G01R 27/04

(52) U.S. Cl. 324/251; 324/66; 324/629

(57) ABSTRACT

A wireless sensor system for detecting electrical power lines in proximity to equipment including a sensor element for detecting the presence of power lines; a transmitter element responsive which generates a wireless signal that conveys the sensed information; and a base station for receiving the wireless signal.

### RELATED APPLICATIONS

This application claims the benefit under 35 U.S.C. § 119(e) of U.S. Provisional Patent Application No. 60/982,184 filed Oct. 24, 2007 titled “Power Line Sensor” which application is incorporated herein by reference in its entirety.

### TECHNICAL FIELD

The present exemplary apparatus and method relate to sensing the proximity of a power line. More particularly, the present exemplary apparatus and method relate to sensing the relative proximity of a piece of equipment to a power line to prevent the equipment from electrically or mechanically contacting the power line.

### BACKGROUND

Overhead electrical power lines present a serious electrocution hazard to personnel in a variety of industries. Overhead lines, typically uninsulated conductors supported on towers or poles, are the most common means of electrical power transmission and distribution, and are exposed to contact by mobile equipment such as cranes and trucks. Equipment contacting energized overhead power line can conduct large amounts of current from the power line through the equipment and into the ground. This can cause electrocution, fire, and damage to both the equipment and the power line. Further, even if there is no conductive electrical path through the equipment to ground, the chassis of the equipment can be elevated to a high voltage, which then can be contacted by personnel who create a grounding path, causing serious electrical shock and burns. Industries where risk of these accidents is greatest include, but are in no way limited to, construction, mining, agriculture, and communication/public utilities. Most commonly, mobile cranes (including boom trucks) are involved in accidents involving power lines.

Methods of preventing dangerous contact of equipment with electrical power lines include de-energizing the power line, restricting equipment motion in proximity to power lines, use of a field observer to alert the operator of impending contact, insulating/electrically isolating the portions of equipment that could contact a power line, and physical barriers to prevent direct contact with an energized line. Because these techniques are expensive, disruptive, and/or lack flexibility, they are not practical in many circumstances. For example, over reliance on field observers is expensive. Further field observers have been shown to be less effective in preventing accidents because of poor viewing positions and distractions.

Accordingly, there is a need for an inexpensive, reliable and versatile sensor system that can detect and minimize hazards that are created by using equipment in proximity to power lines.

### SUMMARY

In one of many possible embodiments, the present exemplary system and method provides for at least one wireless sensor to be placed on a piece of mobile equipment to sense proximity of the mobile equipment relative to power lines and/or to prevent contact by the equipment with the power line. The exemplary sensors can be configured to sense proximity to the power lines through inductive, capacitive, or other means. Additionally sensors can detect charging and current flow through equipment by voltage comparison, induction, or by other similar methods.

### BRIEF DESCRIPTION OF THE DRAWINGS

The accompanying drawings illustrate various embodiments of the present system and method and are a part of the specification. The illustrated embodiments are merely examples of the present system and method and do not limit the scope thereof.

FIG. 1 is an illustrative diagram of one exemplary embodiment of piece of mobile equipment operating in proximity to power lines, according to one exemplary embodiment.

FIG. 2 is an illustrative diagram of one embodiment of wireless sensors placed on a boom that operates in proximity to power lines, according principles described herein.

FIG. 3 is an illustrative diagram of one exemplary embodiment of a wireless sensor configured to sense the electromagnetic signature of a power line, according to principles described herein.

FIG. 4 is an illustrative diagram of one exemplary embodiment of a wireless sensor configured to sense the voltage potential of a power line, according to principles described herein.

FIG. 5 is an illustrative diagram of one exemplary embodiment of a wireless sensor configured to sense the flow of electrical current through equipment in electrical contact with a power line, according to principles described herein.

FIG. 6 is an illustrative diagram of one embodiment of a wireless sensor configured to sense the flow of electrical current through equipment in electrical contact with a power line, according to principles described herein.

FIG. 7 illustrates an exemplary sensor mounting configuration, according to one exemplary embodiment.

Throughout the drawings, identical reference numbers designate similar, but not necessarily identical, elements.

### DETAILED DESCRIPTION

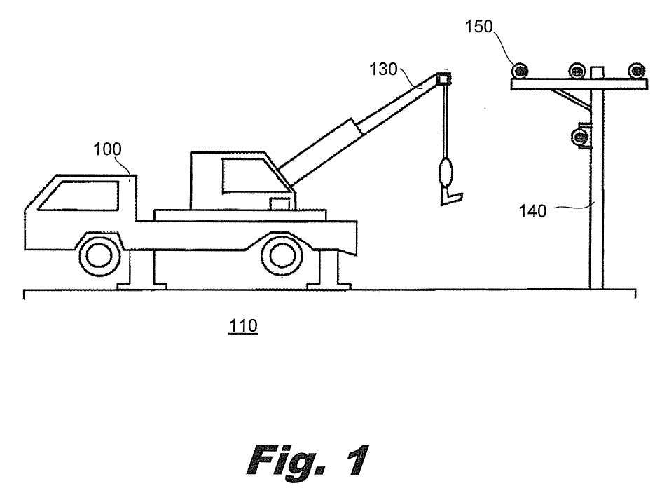

The present exemplary apparatus and method, illustrated by FIGS. 1 through 6, show a variety of wireless sensors configured to enhance the safety and efficiency of equipment operating in proximity to power lines. Particularly, as mentioned above, equipment operating in proximity to power lines has a high likelihood of coming into contact with the power lines and causing equipment damage, and/or potentially injuring or killing those working near by.

FIG. 1 is an illustrative diagram of one exemplary embodiment of a piece of mobile equipment (100) operating in proximity to power lines (150). The equipment is resting on the ground (110) while operating a boom (130) to lift or otherwise manipulate objects (not shown) in proximity to a power pole (140) that supports a variety of power lines (150). Typically a power line carries high voltage power for distribution to end users. The power lines can vary in voltage and current levels that they transport. By way of example and not limitation, a high tension power line may operate at 110,000 volts while a drop line to a house may operate at 115 volts. Similarly, the current transported through the wire can vary based on the line voltage and the current draw by the end users.

When equipment operates in proximity to power lines, the potential for physically or electrically contacting the power line creates a hazard for both the operator of the equipment, the equipment itself, and surrounding workers/observers. The operator who is in direct contact with the equipment faces the possibility of electrocution, fire, and other risks. The equipment itself can be damaged by the passage of high electrical currents/voltages. Surrounding workers can be shocked or electrocuted by touching charged equipment, power broken power lines, or while attempting to rescue an operator who has been electrocuted.

Avoiding power lines while operating equipment can be difficult. In many cases, the operator is focusing on operating the equipment to perform the desired function. This may be digging a trench or lifting pipe into a trench. By placing sensors on areas of the equipment that are most likely to contact the power line, the operator can be alerted to the proximity of the power lines prior to the equipment contacting the power line.

It can be desirable, according to one exemplary embodiment, to have the sensors be wireless. Typically, the portion of the equipment that is in closest proximity to the power lines is a boom or bucket, with many moving parts, extending portions, and/or articulating joints. The passage of wires along these extended booms creates safety, reliability and cost effectiveness issues that have thus far precluded power line proximity sensors from being widely deployed on equipment.

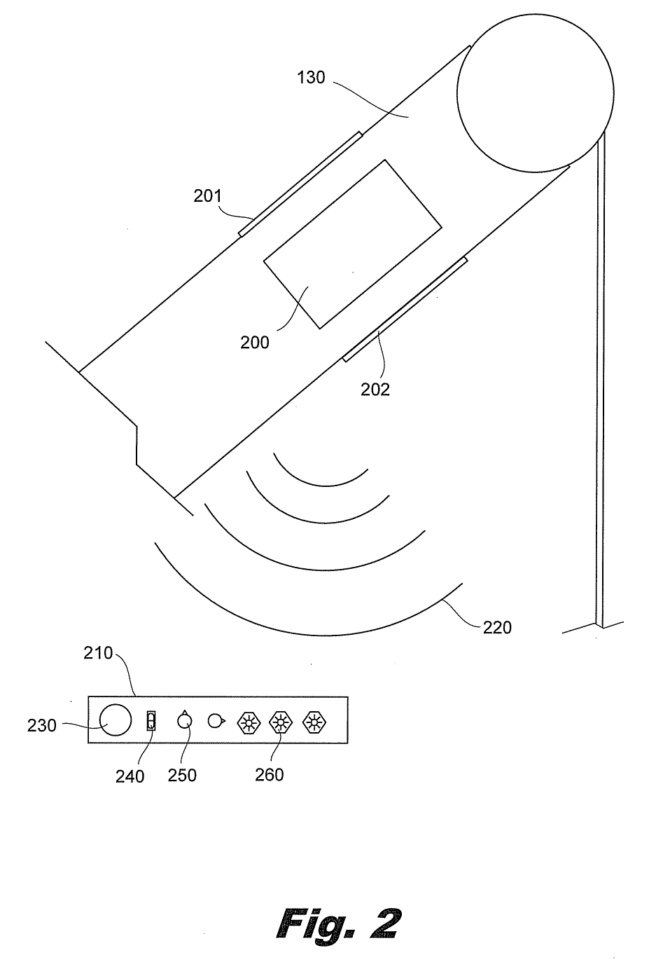

FIG. 2 is an illustrative diagram of one embodiment of wireless sensors (200, 201, 202) placed on a boom (130) that operates in proximity to power lines. The wireless sensors (200, 201, 202) can take a variety of forms and operate in a variety of fashions. According to one exemplary embodiment, the wireless sensor or sensors (200, 201, 202) are configured to transmit a wireless signal to a base station (210). The base station (210) receives the wireless signals (220) and analyzes the signals. If appropriate, the base station (210) can illuminate one or more of the warning lights (260) or sound an audible alarm through speaker (230) to indicate that at least one of the sensors (200, 201, 202) are close enough to a power line to merit notifying the equipment operator.

The exemplary base station (210) configured to receive and interpret signals transmitted by the wireless sensors (200, 201, 202) can also, according to one exemplary embodiment, have a variety of user accessible controls such as a power switch (240) and/or dials (250). The dials (250) could be used to control a range of functions including the sensitivity of a wireless receiver in the exemplary base station (210) or base alarm levels. When the operator hears or sees an alarm the operator becomes aware of a potentially dangerous situation and can work to solve the problem. An audible alarm may include a volume control, which may be manually adjusted or automatically adjusted in response to ambient/background noise levels. According to this exemplary embodiment, the exemplary base station (210) will include a microphone device and a processor. The microphone device receives ambient noise and converts it into a digital signal that can then be transmitted to and analyzed by the processor. Once received, the processor may adjust the volume level of the audible alarm to compensate for the level of ambient noise present around the device. Similarly, according to one exemplary embodiment, it may be desirable to prevent adjustment of the volume to levels too low to be recognized by a user.

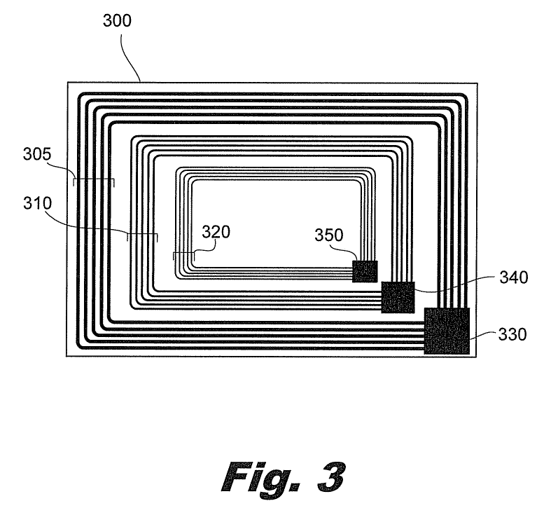

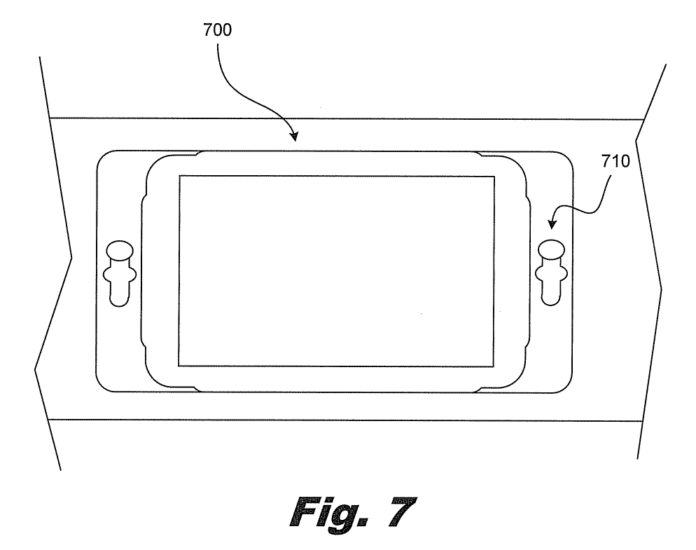

FIG. 3 is an illustrative diagram of one embodiment of a wireless sensor (300) configured to sense the electromagnetic signature of a power line (130, FIG. 1), according to principles described herein. The exemplary wireless sensor (300) is a thin and potentially flexible unit that is designed to be attached to a boom or other equipment element that may come in proximity to power lines. The sensor (300) can be attached in a variety of ways, including, but in no way limited to, adhesive bonding, bolting, or other fastening means. The sensor may be attached to a desired machine with a permanent surface mounting, or a mounting that allows removal of the sensor, such as a keyhole mounting configuration (710), as shown in the exemplary embodiment of FIG. 7.

According to the exemplary embodiment illustrated in FIG. 3, the sensor (300) includes a first antenna (305) with a relatively large area and/or efficient configuration. The first antenna is connected to a first electronics segment (330). The electronics segment (330) may contain signal conditioning circuitry, a transmitting antenna, a battery, and/or other components. According to one exemplary embodiment, the electronics segment (330) is powered by the illumination of the first antenna (305) and therefore does not require a battery. Further, the electronics segment (330) may utilize the first antenna (305) to both receive power and to transmit data.

In an alternative exemplary embodiment, the electronics segment (330) contains a long life battery that powers the electronics and provides the power for the transmission of the wireless signal (220, FIG. 2). The long life battery can be of any of a variety of types and can be configured for a useable lifetime of ten years or more.

According to one exemplary embodiment, the signal transmitted by the exemplary sensor (300) can be in digital or analog format. According to one exemplary embodiment, the transmitted signal is a digital identifier that is received by the base station (210) which can then identify which sensor has transmitted the signal.

As shown in the exemplary embodiment of FIG. 3, the sensor (300) may include a plurality of antenna/electronic segment pairs each of which comprise a sub-sensor, including a second antenna (310) coupled to a second electronics segment (340) and a third antenna (320) coupled to a third electronics segment (350).

The antennas and corresponding electronics can be configured in a variety of orientations, geometries, and configurations. According to one exemplary embodiment, the variation in the antenna geometries gives each sub sensor (comprised of an antenna/electronics pair) a varying sensitivity to an electromagnetic field. As the boom (130) approaches a power line, the sensor (300) passes into the electromagnetic field generated by the passage of current through the power line (150). According to the exemplary configuration, the first sub sensor (305, 330) is the most efficient at sensing the electromagnetic field and converting the electromagnetic field into energy. This energy powers the electronics segment (330) which transmits its wireless signal to the base station. As the boom moves closer to the power line (150) the second sub sensor (310, 340) is illuminated by the field and generates a wireless signal that is transmitted to the base station. These signals may result in the illumination of a warning light or lights (260), the sounding of an audible alarm, or some other notifying signal configured to convey the possible danger to an operator of the equipment. For example, when the first sub sensor (305, 330) transmits its wireless signal, the base station (210) may illuminate a first yellow warning light. When the second signal is received, indicating a more precarious relative position between the boom (130) and a power line, the base station (210) may illuminate a second red warning light. As the boom (130) continues to move closer to the power line, the final sub sensor (320, 350) becomes illuminated and transmits its wireless signal. At this point, the base station may flash a warning light (260) and/or sound an audible alarm (230) to demonstrate that the equipment (130) has reached a dangerous proximity to the power line (150).

In cases where there is little or no current flowing through the power line, only a minimal electromagnetic field may be present around the power line. However, the power line can still have a dangerous voltage present. This can occur when a power line is broken or when there is little current demand. Some traditional sensor types may not be effective when there is only a low electromagnetic field is present, as they rely on a high electromagnetic field to identify the afore-mentioned dangerous situations.

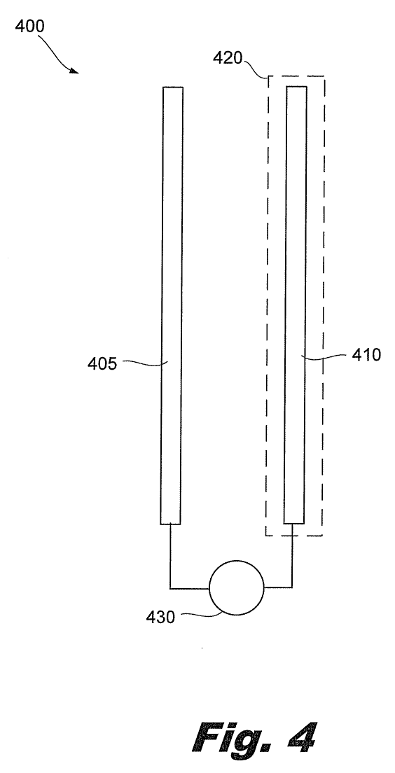

FIG. 4 is an illustrative diagram of one embodiment of a wireless capacitive sensor (400) configured to sense the voltage potential of a power line (150, FIG. 1), according to one exemplary embodiment. As illustrated in FIG. 4, a first plate (405) is exposed to the voltage potential surrounding the power line. A second plate (410) is at least partially isolated from first plate (405) and from the voltage potential of the power line (150) as shown by the dotted line (420). The voltage difference between the first plate (405) and the second plate (410) is measured by sensor (430).

This capacitive technique for measuring proximity to power lines has a variety of advantages. The capacitive technique is less likely to be susceptible to varying current loads through the power line because the capacitive sensor (400) senses the voltage potential that surrounds power lines. Further, even if the power line is broken, the power line may have a dangerous voltage, which will be detected via the capacitive technique. Consequently, the capacitive sensor (400) may be better adapted to sensing broken power lines.

The capacitive sensor elements used in the present exemplary capacitive sensor may assume a variety of shapes and configurations. For example, according to one exemplary embodiment, the plates (405, 410) may be shaped like a globe or any other geometry to improve the omnidirectionality and/or other characteristics of the sensor. In one exemplary embodiment the second plate (410) is replaced by an internal voltage reference to which the voltage of the first plate (405) is compared. Additionally, the first plate (405) may be a portion of the equipment itself.

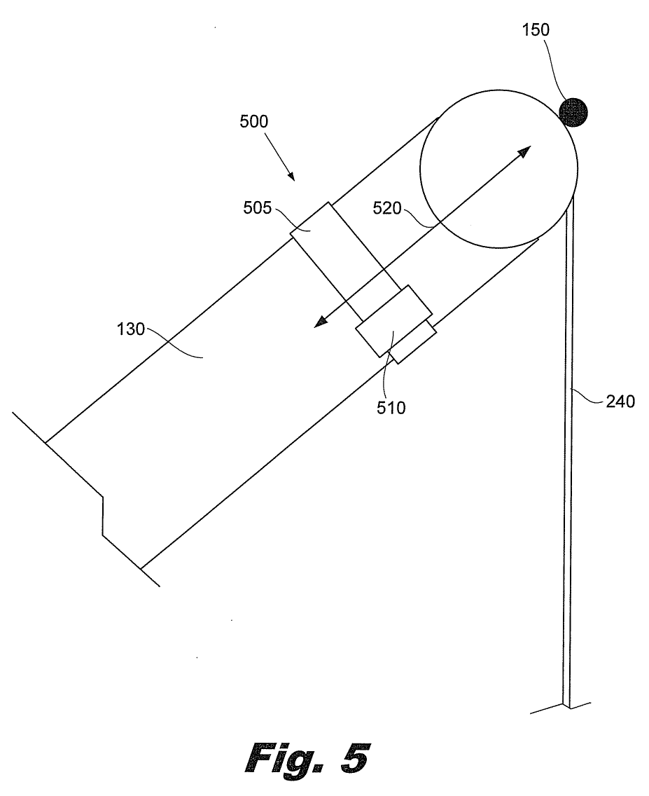

FIG. 5 is an illustrative diagram of one embodiment of a wireless sensor (500) configured to sense the flow of electrical current (520) through equipment (130) in electrical contact with a power line (150), according to one exemplary embodiment. There are several circumstances in which current can flow through a piece of equipment (130, 100). In high voltage situations where the equipment is not close enough to directly electrically contact the power line, a corona discharge may occur that transmits low currents through the equipment (100) to the ground. This type of discharge rarely produces harmful currents. As the equipment continues to approach the power line, the air between the equipment and power line can be become ionized, creating a conductive path from the power line to the equipment. An arc can then travel over the conductive air path, through the equipment, and into the ground.

In another scenario, the voltage from the power line is insufficient to create an arc. In this case, until the equipment physically contacts the power line, no current passes through the equipment. If the equipment is sufficiently isolated from the ground (by rubber tires or otherwise) only a transient current passes through the equipments. When the equipment reaches a high enough voltage (usually the same voltage as the power line) the current flow stops until there is a path to the ground. Bystanders or coworkers who approach and touch the otherwise normal appearing equipment can then become the path of least resistance to the ground. As a person touches the equipment, current flows from the power line, down the equipment, and through the person to the ground. In the situation where the equipment becomes dangerously charged, a capacitive sensor (not shown) could be used to detect the voltage and wirelessly transmit data that could alert a base station and/or sound an external alarm.

However, if the equipment has insufficient isolation from the ground (such as when hydraulic feet are extended for stability), the current will flow through the equipment and into the ground. In many cases, the operator may be entirely unaware of the current flowing through the equipment until he or she steps down from the equipment to the ground and is shocked or electrocuted.

Consequently, sensing current flow into the equipment can provide an additional method of improving the safety for workers and equipment operating around power lines. FIG. 5 shows a wireless current sensor (500) that comprises a conductive portion (505) that encircles the boom (130) and a detector/transmitter portion (510), according to one exemplary embodiment. When current (520) flows through the boom (130), the wireless sensor detects the current and sends a wireless signal to a base station (210, FIG. 2) to generate a signal to alert the operator or others of the dangerous situation. In one embodiment, the wireless current sensor (500) could activate an external flashing light and/or siren that would alert surrounding bystanders and/or coworkers.

The conductive portion (505) of the wireless current sensor (500) can take the form of insulated wire coil, a thin conductive film, or other insulated conductor that forms a toroidal or other conforming shape configured to pass around a boom or other piece of equipment such as a hydraulic ram.

The detector/transmitter portion (510) may utilize a variety of sensors to directly or indirectly detect the passage of current through the equipment, including Hall Effect sensors, current sensors, voltage sensors or another appropriate detector. According to one exemplary embodiment, the detector/transmitter portion (510) of the wireless current sensor (500) can detect the transient current surge that occurs when the equipment becomes charged but is sufficiently isolated from the ground to prevent the passage of current from the power line to the ground.

As discussed above, the detector/transmitter portion (510) can be passively or actively powered according to the circumstances and the implemented design. The detector transmitter portion (510) can then wirelessly broadcast an analog or digital signal that alerts the base station to the passage of current into the equipment.

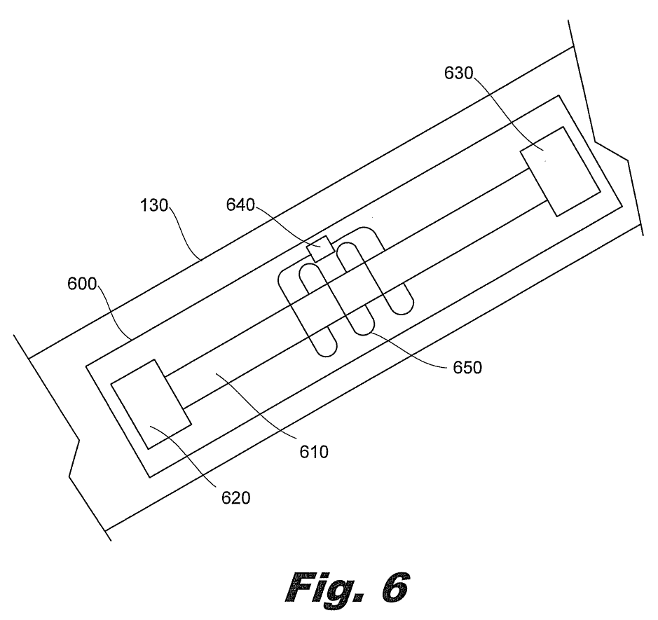

FIG. 6 is an illustrative diagram of another embodiment of a wireless sensor (600) configured to sense the flow of electrical current through equipment in electrical contact with a power line, according to one exemplary embodiment. In this figure, the sensor (600) is attached to the side of a boom (130). The sensor comprises a conductor element (610) that is in electrical contact with the boom via a first conductive pad (620) and a second conductive pad (630). A coil (650) passes around the conductor element (610) and attaches to a detector/transmitter element (640). The coil could be adapted to effectively measure the passage of current in a variety of manners including, but in no way limited to, altering the number of coils, the coil geometry, or introducing a iron core into the coil assembly. When current passes through the equipment (130), a portion of the current travels through the conductor (610) and is detected in a manner similar to that described in FIG. 5. The conductor (610) may have a variety of geometries, including a flat plate, a film, a wire or a rod. Additionally, the conductor may be attached in a variety of ways including welding, fasteners, crimping, adhesive means, or any other connecting system.

According to one exemplary embodiment, the wireless current sensor (600) is a thin flat rectangular shape that configured to be adhered to the side of a boom (130) or other advantageous location on the equipment. One potential advantage of this sensor is that it can be placed in a wide variety of locations and does not have the requirement of having a continuous conductor passing around a portion of the equipment. Further, because the conductor (610) is of a known material, geometry, and conduction, the calibration of the sensor is simplified.

The detectors illustrated and discussed above could be combined to create a sensor package that is configured to make a variety of measurements to improve the safety when working with equipment around power lines. For example, according to one exemplary embodiment, the electromagnetic sensor (300), the capacitive sensor (400) and the current sensor (600) could be combined into a single package that could be mounted in a variety of locations on the equipment. Using standard circuit techniques for printing antenna and other elements on flexible substrates, the cost of the sensors could be minimized. Additionally, multiple sensor packages could be placed at advantageous locations on the equipment for more optimum sensing.

The wireless transmitters contained within the present exemplary sensors allow the sensor to be placed without wires. This increases the potential locations for the sensors and allows greater flexibility in placing the sensors. The sensor may be less expensive because no wiring is required for installation of the sensors. Further the resulting sensor may be more reliable because there is no wiring that could fray, fatigue or break at flexure or extension joints. Additionally, each sensor could be individually identifiable if the wireless transmission included a serial number or other identifying information.

In the construction industry, components that may have sensors in place are often replaceable or interchangeable. For example, a bucket or arm of a track hoe may be interchangeable. An additional advantage of wireless sensors is that there are no connections to be disengaged and subsequently reengaged when components are interchanged. In one exemplary embodiment the base station is adapted to receive wireless transmissions from all compatible sensors. The sensors each transmit a unique identifier which allows the base station to discriminate between sensors.

Advanced sensors may combine range and position data with other sensors. By way of example and not limitation, the geometry and range of charged obstructions could be determined by using an array of detectors, acoustic sensing and ranging, or by using radio wave detection and ranging techniques. A multiple array of electromagnetic or other detectors could sense the curvature of the electrical field and provide an estimate of the range. Range and position data could be displayed in a graphical format on a base receiver.

The sensor may alternatively be disposed within an enclosure (700), as in the embodiment of FIG. 7. The sensor may be disposed within an enclosure made of a material that does not interfere with the ability of the sensors to detect electromagnetic waves, electric potential, or current, such as a plastic electronics enclosure. One embodiment may include an enclosure (700) made from polycarbonate or other suitable material having properties for temperature and impact resistance. The enclosure may be flame retardant and may also be UV stabilized for outdoor use. The enclosure may also include a silicone gasket or similar gasket for sealing the enclosure (700) to protect against water and dust and other materials that may interfere with proper operation of the sensor outdoors. In some exemplary embodiments, the enclosure may include a textured or recessed surface suitable for printed graphics, labels or membrane keypads.

As previously described, the enclosure (700) may be mounted on the boom or other equipment element using a keyhole mounting configuration (710). This may allow for the enclosure to be removed from the mounting element, such that the sensor may be tested, updated, or otherwise modified if desired. The enclosure may also use any other removable means of mounting. Alternatively, the enclosure may be mounted on the equipment element in a permanent manner.

In conclusion, the present exemplary systems and methods provide for an independently mountable wireless system that will readily notify machine operators and surrounding observers when the machine being operated is dangerously close to a power line or other dangerous power source. Particularly, as mentioned above, a number of wireless sensors, constructed as detailed above, may be mounted to the boom or other part of a machine, in connection with a base station, to readily notify machine operators and nearby workers/observers when any portion of the machine is too close to a power line.

The preceding description has been presented only to illustrate and describe exemplary embodiments of the present system and method. It is not intended to be exhaustive or to limit the system and method to any precise form disclosed. Many modifications and variations are possible in light of the above teaching. It is intended that the scope of the system and method be defined by the following claims

What is claimed is:

1. A wireless sensor system for detecting electrical power lines in proximity to a piece of equipment comprising:
a sensor element configured to detect the presence of power lines;
a transmitter element responsive to said sensor element, said transmitter element configured to transmit a wireless signal when activated by said sensor element; and
a base station configured receive said wireless signal and generate a warning in response to said wireless signal.

2. The wireless sensor system of claim 1, wherein said sensor element further comprises an electromagnetic sensor.

3. The wireless sensor system of claim 2, wherein said sensor element further comprises a plurality of sub-sensors, each sub-sensor being configured to activate at a different level of electromagnetic flux concentration.

4. The wireless sensor system of claim 3, wherein said sensor element is passive.

5. The wireless sensor system of claim 1, wherein said sensor element further comprises a capacitive sensor configured to detect voltage potential.

6. The wireless sensor system of claim 1, wherein said sensor element further comprises a current sensor configured to detect currents passing through said equipment.

7. The wireless sensor system of claim 6, wherein said sensor element further comprises a current sensor configured to directly measure current flowing through said equipment.

8. The wireless sensor system of claim 6, wherein said sensor element further comprises a current sensor configured to sense current flowing through a separate conductor;
said separate conductor being configured such that a portion of current flowing through said equipment is routed through said separate conductor.

9. The wireless sensor system of claim 6, wherein said sensor element further comprises an inductive sensor.

10. The wireless sensor system of claim 6, wherein said sensor element further comprises a Hall Effect sensor.

11. The wireless sensor system of claim 1, wherein said wireless signal further comprises an identifying number configured to uniquely identify said sensor element.

12. The wireless sensor system of claim 11, wherein said sensor element further comprises at least one of an electromagnetic sensor, a voltage potential sensor, or a current sensor.

13. The wireless sensor system of claim 12, wherein said sensor element further comprises a plurality of sensor elements, said sensor elements being attached to said equipment.

14. The wireless sensor system of claim 1, wherein said sensor element comprises at least one of an array of electromagnetic sensors, acoustic detection and range sensor, or a radio detection and range sensor.

15. The sensor system of claim 14 wherein said base station is configured to receive said wireless signal and represent said wireless signal in a graphical display.

16. The sensor system of claim 1, wherein said sensor element is disposed within an enclosure.

17. The sensor system of claim 16, wherein said enclosure comprises a gasket configured to seal said sensor element within said gasket.

18. The sensor system of claim 16, wherein said enclosure comprises a material that allows electromagnetic waves to pass through said enclosure to said sensor element.

19. The sensor system of claim 18, wherein said material comprises a polycarbonate.

20. The sensor system of claim 16, wherein said enclosure is configured to be removably attached to said equipment without tools.
